(19) United States
(12) Patent Application Publication
(10) Pub. No.: US 2007/0154818 A1
(43) Pub. Date: Jul. 5, 2007

(54) Integrated color filter

(75) Inventors: Chi-Min Chen, Taichung County (TW); Gwo-Sen Lin, Taichung City (TW)

Correspondence Address: BACON & THOMAS, PLLC, 625 SLATERS LANE, FOURTH FLOOR, ALEXANDRIA, VA, 22314, US

(73) Assignee: Wintek Corporation, Taichung (TW)

(21) Appl. No.: 11/319,633

(22) Filed: Dec. 29, 2005

(51) Int. Cl. G03F 1/00

(52) U.S. Cl. 430/7

(57) ABSTRACT

An integrated color filter includes a substrate with a black matrix thereon to define a plurality of sub pixels on a surface thereof. A plurality of color filter units disposed in the sub pixels respectively, which are made of pigment doping organic material. The organic material is fluorescence or phosphorescence organic material to provide the image of the display with well saturation and luminance.

### BACKGROUND OF THE INVENTION

1. Field of the Invention

The present invention relates generally to a color filter of a display, and more particularly to an integrated color capable of increasing luminance of the display panel.

2. Description of the Related Art

Color filter is an important component of a full-color display, which is incorporated in liquid crystal display or organic electroluminescent display using white light. Said color filter includes a plurality of red, green and blue filter units arranged as an array pattern. When the light provided form the backlight passes through these red, green and blue filter units, it provides a color image.

Although the color filter provides the display with full-color, the color filter become a lower light transmittance when the display is asked to provide a higher saturation. The light provided from the backlight will travel through multilayer structure, such as liquid crystal layer and color filter, of the display, so that the luminance of the display is about 10% of the luminance of backlight. As a result, the display has a lower luminance. Although the display can be provided with a high-luminance backlight to increase the luminance of the display, it makes a huge load to the backlight. In addition, some filter unites are added with undissolved inorganic light-emitting particles that the particles are lighted by the light of backlight to increase the luminance. Such structure is depended on a high-energy light source, such as UV light or blue-purple light, that is not the best choice for a hand-held electronic device to provide UV light or blue-purple light.

### SUMMARY OF THE INVENTION

The primary objective of the present invention is to provide an integrated color filter, which makes a display with well saturation and luminance.

According to the objective of the present invention, an integrated color filter comprises a substrate defining a plurality of sub pixels on a surface thereof; and a plurality of color filter units disposed in the sub pixels respectively, which are made of pigment doping organic material, wherein the organic material is fluorescence or phosphorescence organic material.

### BRIEF DESCRIPTION OF THE DRAWINGS

FIG. 1 is a sectional view of a preferred embodiment of the present invention;

FIG. 2 and FIG. 3 are sectional views of the preferred embodiment of the present invention incorporated in different organic electroluminescent displays;

FIG. 4 is a sketch diagram of the preferred embodiment of the present invention incorporated in COA integrated color filter of the thin film transistor liquid crystal display; and

FIG. 5 is a sketch diagram of the preferred embodiment of the present invention incorporated in AOC integrated color filter of the thin film transistor liquid crystal display.

### DETAILED DESCRIPTION OF THE INVENTION

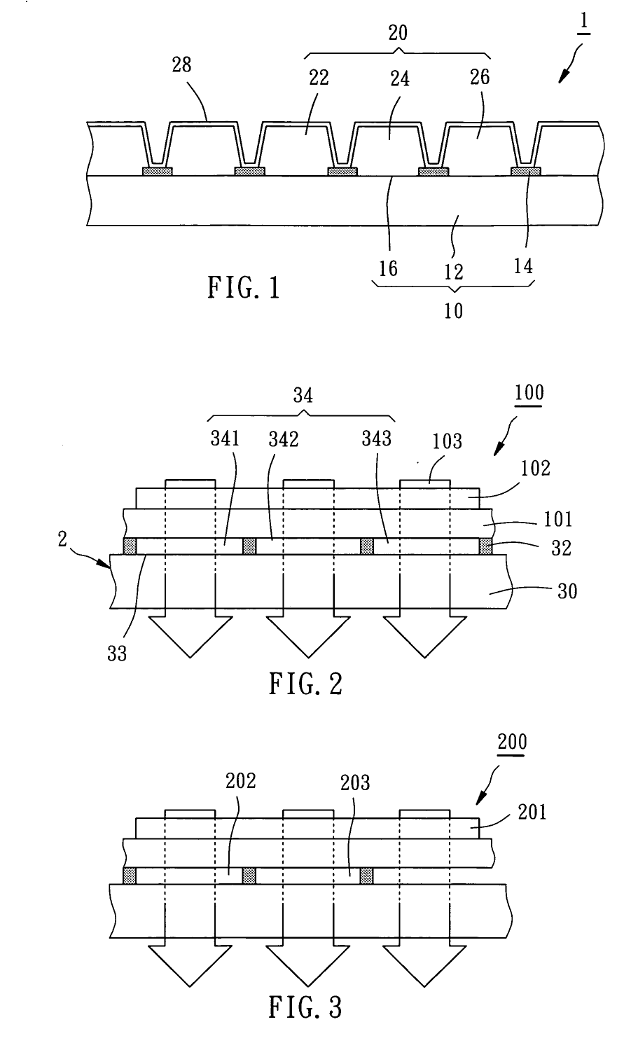

FIG. 1 shows an integrated color filter 1 of the preferred embodiment of the present invention, which is an essential component of a full-color liquid crystal display, mainly comprising a substrate 10 and a plurality of color filter units 20.

The substrate 10 includes a transparent member 12 and a black matrix 14, which define a plurality of sub pixels 16, on the transparent member 12.

The color filter units 20 include a plurality of red filter units 22, green filter units 24 and blue filter units 26, each of which is arranged in the sub pixels 16 with a predetermined order. A protective film 28 covers the color filter units 20 to prevent them from damage.

Said red, green and blue filter units 22, 24 and 26 are made of pigment providing the corresponding color doping organic material. The organic material may be fluorescence material or phosphorescence material.

In the present embodiment, the pigment for the red filter units 22 is series number PR7120 produced by EVERLIGHT GROUP and the organic material is DCJTB produced by KODAK, which provides fluorescence. For mixing DCJTB and PR7120, DCJTB is put in a solution first, such as MeOH, to provide an organic saturated solution, and then drip the organic saturated solution in PR7120. After removing MeOH, it will have the red filter units 22 of DCJTB and PR7120. It has to be mentioned that the pigment of the red filter units 22 may dope phosphorescence material, such as PtOEP produced by Universal Display Corp., or Irpig3 or Irpig2acac produced by CANON Inc.

The pigment for the green filter units 24 of the invention is series number PG8120 produced by EVERLIGHT GROUP and the organic material is C545T produced by KODAK, which provides fluorescence. For mixing C545T and PG8120, C545T is put in a solution first, such as MeOH, to provide an organic saturated solution, and then drip the organic saturated solution in PG8120. After removing MeOH, it will have the green filter units 24 of C545T and PG8120. It has to be mentioned that the pigment of the green filter units 24 may dope phosphorescence material, such as PtOEP produced by Universal Display Corp., or Irpig3 or Irpig2acac produced by CANON Inc.

The pigment for the blue filter units 26 of the invention is series number PB9120 produced by EVERLIGHT GROUP and the organic material is PB9120 produced by KODAK, which provides fluorescence. For mixing IDE120 and PB9120, IDE120 is put in a solution first, such as MEOH, to provide an organic saturated solution, and then drip the organic saturated solution in PB9120. After removing MeOH, it will have the blue filter units 26 of IDE120 and PB9120. It has to be mentioned that the pigment of the blue filter units 26 may dope phosphorescence material, such as FIrpic or Fir6 produced by Universal Display Corp.

Above is the description of the components of the integrated color filter 1 of the present invention. The color filter units 20 include pigment doping organic material that is excited by an external power to excited state to emit fluorescence or phosphorescence. Said external power may be change of light or temperature, and the present invention uses light to be the external power. When the light, both of the light provided from the external light source of the display and the light provided from the backlight in the display, passes through the color filter units 20, the display shows a full-color image with well saturation. The display will have high luminance because the color filter units 20 provide fluorescence or phosphorescence. The description of increasing luminance of the display will be described later.

It has to be mentioned that said embodiment provides all of the red, green and blue filter units 22, 24 and 26 doped with organic material providing fluorescence or phosphorescence, but it also may be one or two filter units doped with organic material providing fluorescence or phosphorescence depending on the practice requirement.

The inventor makes a test for the luminance of the filter united with the pigment doping the organic material providing fluorescence. The light source for the test may be white light or blue light, and the present test chooses white light.

Referring to Table 1, it shows the luminance change according to the red filter units 22 with various percentages of red pigment and DCJTB organic fluorescence material.

TABLE 1

| red pigment:organic fluorescence | | | luminance |
|---|---|---|---|
| material (volume percentage) | CIE-X | CIE-Y | (unit: cd/m²) |
| 100:0 | 0.624 | 0.359 | 365 |
| 100:0.03 | 0.621 | 0.359 | 406 |
| 100:0.02 | 0.618 | 0.36 | 404 |
| 100:0.01 | 0.618 | 0.36 | 402 |
| 100:0.009 | 0.621 | 0.36 | 393 |
| 100:0.008 | 0.624 | 0.359 | 390 |
| 100:0.007 | 0.624 | 0.359 | 387 |
| 100:0.006 | 0.623 | 0.359 | 378 |

As shown in Table 1, the conventional red filter unit without any fluorescence or phosphorescence organic material has a luminance (356 cd/m²) less than the red filter units 22 doping DCJTB, the organic fluorescence material, of the present invention. Table 1 also teaches that the optimum ratio of the red pigment and the organic fluorescence material is in a range between 100:0.03 and 100:0.006.

Referring to Table 2, it shows the luminance change according to the green filter units 24 with various percentages of green pigment and C545T organic fluorescence material.

TABLE 2

| red pigment:organic fluorescence | | | luminance |
|---|---|---|---|
| material (volume percentage) | CIE-X | CIE-Y | (unit: cd/m²) |
| 100:0 | 0.163 | 0.525 | 2312 |
| 100:0.01 | 0.163 | 0.521 | 2669 |
| 100:0.02 | 0.163 | 0.524 | 2573 |
| 100:0.03 | 0.163 | 0.518 | 2557 |
| 100:0.04 | 0.163 | 0.518 | 2504 |
| 100:0.05 | 0.164 | 0.521 | 2447 |
| 100:0.1 | 0.165 | 0.521 | 2386 |
| 100:0.2 | 0.166 | 0.525 | 2384 |
| 100:0.3 | 0.166 | 0.525 | 2345 |

As shown in Table 2, the conventional green filter unit without any fluorescence or phosphorescence organic material has a luminance (2312 cd/m²) less than the green filter units 24 doping C545T, the organic fluorescence material, of the present invention. Table 1 also teaches that the optimum ratio of the red pigment and the organic fluorescence material is in a range between 100:0.01 and 100:0.3.

In conclusion, the pigment doping a predetermined percentage of fluorescence or phosphorescence organic material can increase the luminance of the color filter units 20 so as to increase the luminance of the image. The present invention has no drawback of greater load of the backlight when it has to provide light with greater luminance to increase the luminance of image. The present invention also has no drawback of excitation of high energy light (e.g. UV light) when the undissolved inorganic light-emitting particles are added into the filter unit.

In the present embodiment, the integrated color filter 1 is used in a CSTN type liquid crystal display. Of course, the technique of the present invention can be used in the color filters of other types of displays. For instance, FIG. 2 shows a color organic electroluminescent display 100 including an integrated color filter 2, an ITO anode 101, a light-emitting layer 102 to provide white light and a cathode 103. The integrated color filter 2 is as same as the color filter 1 described above including a transparent member 30, a black matrix 32 and a plurality of sub pixels 33 and color filter units 34 surrounded and defined by the black matrix 32. The color filter units 34 are made of pigments doping a predetermined percentage of fluorescence or phosphorescence organic materials, each of which includes a plurality of red filter units 341, green filter units 342 and blue filter units 343 corresponding to the sub pixels 33 respectively. The ITO anode 101 is on the color filter units 34, and the light-emitting layer 102 is on the ITO anode 101, and the cathode 103 is on the light-emitting layer 102. The display 100 uses the color filter method to provide full-color image according to the structure and the mode of light emitting.

FIG. 3 shows another color organic electroluminescent display 200, which use color change medium (CCM) to provide full-color image. The structure of the display 200 is similar to that of above display 100, except that the display 200 has a light-emitting layer 201 providing blue light and the color filter units including red filter units 202 and green filter units 203 only. The fluorescence or phosphorescence organic material is doped in the red filter units 202 and the green filter units 203.

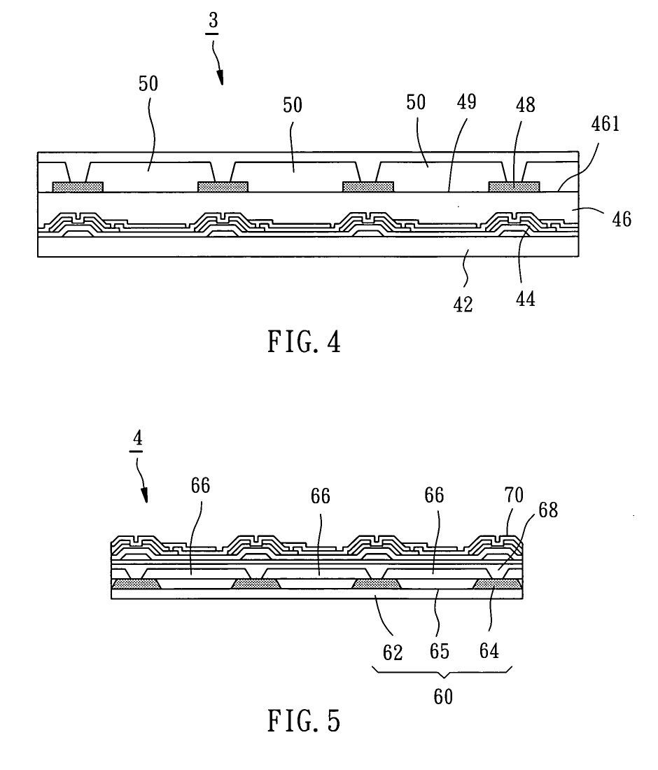

FIG. 4 and FIG. 5 shows the technique of the present invention is used in the integrated color filters of the thin film transistor liquid crystal displays (TFT LCD). The displays are named as color filter on array (COA) display and array on color filter (AOC) display according to the different processes.

FIG. 4 shows an integrated color filter 3 of the COA display, which includes a thin film transistor array substrate 40 and a plurality of color filter units 50. The thin film transistor array substrate 40 includes a transparent member 42, a plurality of thin film transistors 44, an insulating layer 46 and a black matrix 48. The thin film transistors 44 are arranged on the transparent member 42 in an array pattern. The insulating layer 46 covers the thin film transistors 44 and the transparent member 42. The insulating layer 46 has a flat surface 461. The black matrix 48 is on the insulating layer 46 to surround and define a plurality of sub pixels 49 and color filter units 50. The color filter units 50 include pigments doping fluorescence or phosphorescence organic materials.

FIG. 5 shows an integrated color filter 4 of the AOC display, which includes a substrate 60, a plurality of color filter units 66, a flat layer 68 and a plurality of thin film transistors 70. The substrate 60 includes a transparent member 62 and a black matrix 64 on the transparent member 62. The color filter units 66 are arranged in an order of red, green and blue at a plurality of sub pixels 65 surrounded and defined by the black matrix 64. The color filter units 6 include pigments doping fluorescence or phosphorescence organic materials. The flat layer covers all of the color filter units 66 to support the thin film transistors 70 thereon.

What is claimed is:

1. An integrated color filter, comprising:
a substrate defining a plurality of sub pixels on a surface thereof; and
a plurality of color filter units disposed in the sub pixels respectively, which are made of pigment doping organic material, wherein the organic material is fluorescence or phosphorescence organic material.

2. The integrated color filter as defined in claim 1, wherein the color filter units comprise a plurality of red filter units, green filter units and blue filter units, and the organic material is doped in at least one color of filter units.

3. The integrated color filter as defined in claim 2, wherein the pigment of the red filter units is PR7120 material.

4. The integrated color filter as defined in claim 2, wherein the pigment of the green filter units is PG8120 material.

5. The integrated color filter as defined in claim 2, wherein the pigment of the blue filter units is PB9120 material.

6. The integrated color filter as defined in claim 2, wherein the fluorescence material of the red filter units is DCJTB material.

7. The integrated color filter as defined in claim 2, wherein the phosphorescence material of the red filter units is PtOEP, Irpig3 or Irpig2acac material.

8. The integrated color filter as defined in claim 2, wherein the fluorescence material of the green filter units is C545T material.

9. The integrated color filter as defined in claim 2, wherein the phosphorescence material of the green filter units is PtOEP, Irpig3 or Irpig2acac material.

10. The integrated color filter as defined in claim 2, wherein the fluorescence material of the blue filter units is IDE102 material.

11. The integrated color filter as defined in claim 2, wherein the phosphorescence material of the blue filter units is Firpic or Fir6 material.

12. The integrated color filter as defined in claim 2, wherein a volume percentage of the red pigment and the organic material is in a range between 100:0.03 and 100:0.006.

13. The integrated color filter as defined in claim 2, wherein a volume percentage of the green pigment and the organic material is in a range between 1:0.01 and 1:0.3.

14. The integrated color filter as defined in claim 1, wherein the substrate has a transparent member and a black matrix on the transparent member to surround the sub pixels.

15. The integrated color filter as defined in claim 1, wherein the substrate is a thin film transistor array substrate, which comprises:
a transparent member;
a plurality of thin film transistors arranged on the transparent member in an array pattern;
an insulating layer covering the transparent member and the thin film transistors, which has a surface; and
a black matrix disposed on the surface of the insulating layer to surround the sub pixels.
